(19) United States
(12) Patent Application Publication
(10) Pub. No.: US 2011/0156193 A1
(43) Pub. Date: Jun. 30, 2011

(54) SEMICONDUCTOR COMPONENT AND METHOD OF FABRICATING SEMICONDUCTOR COMPONENT

(75) Inventors: Atsushi NAKAMURA, Miyazaki (JP); Masami IKEGAMI, Miyazaki (JP)

(73) Assignee: OKI SEMICONDUCTOR CO., LTD., Tokyo (JP)

(21) Appl. No.: 12/977,982

(22) Filed: Dec. 23, 2010

(30) Foreign Application Priority Data
Dec. 28, 2009 (JP) 2009-298178

(51) Int. Cl. H01L 31/068; H01L 31/18

(52) U.S. Cl. 257/435; 438/98; 257/E31.057; 257/E31.001; 257/E31.125

(57) ABSTRACT

There is provided a semiconductor component including: a semiconductor substrate of a first conduction type; a semiconductor layer of a second conduction type that is formed on the semiconductor substrate and is PN-joined with the semiconductor substrate; an insulator layer laminated on the semiconductor layer; a metal layer laminated on the insulator layer at a pre-specified region; a semiconductor of the second conduction type at a side of the semiconductor layer at which the insulating layer is laminated, the semiconductor being formed directly under the metal layer such that incident light that is incident from the metal layer side is not illuminated onto the semiconductor layer, and the semiconductor containing more impurities than the semiconductor layer; and a conduction portion that conducts between the metal layer and the semiconductor.

### CROSS-REFERENCE TO RELATED APPLICATION

This application is based on and claims priority under 35 USC 119 from Japanese Patent Application No. 2009-298178, filed on Dec. 28, 2009, the disclosure of which is incorporated by reference herein.

### BACKGROUND

1. Technical Field

The present invention relates to a semiconductor component and a semiconductor component fabrication method, and particularly relates to a semiconductor component that is a light detection component of a light sensor, and a fabrication method of the semiconductor component.

2. Related Art

Generally, a photodiode serves as a semiconductor component that is a light detection component used in a light sensor. For example, in Japanese Patent Application Laid-Open (JP-A) No. 10-284753, a photodiode is recited in which a PN junction portion of the photodiode is constituted by a silicon (Si) substrate with a low doping density and an epitaxial layer.

Types of light sensor include an ambient light sensor that is capable of changing a current output in accordance with the brightness of the surroundings. An example of a light detection component that is used in this kind of ambient light sensor is illustrated in FIG. 6 and FIG. 7. FIG. 6 is a plan view, seen from a side from which light is incident, showing an example of schematic structure of a light detection component 100 of a related art ambient light sensor (hereinafter referred to simply as the light detection component 100). FIG. 7 is a sectional diagram showing an example of a section taken along line B-B of the light detection component 100 of the related art ambient light sensor.

As illustrated in FIG. 6, the related art light detection component 100 is provided with a structure in which, if viewed from the side from which light is incident, a field layer 118 is formed inside a metal layer 127, which is an anode electrode, and an N-well layer 114 is formed inside the field layer 118. Further, a sensor region 111, which is a light detection portion, is formed inside the N-well layer 114, and an N⁺ layer 116 is formed over substantially the whole surface inside the sensor region 111. Further structure is provided in which a metal layer 126 is formed so as to cover portions of each of the N⁺ layer 116, the sensor region 111, the N-well layer 114 and the field layer 118. Structure is further provided in which a contact hole 123 is formed in the metal layer 126, and a plug 124 is formed in the contact hole 123.

As illustrated in FIG. 7, the N-well layer 114 is formed to be PN-joined to the top of a P-sub layer 112. The N⁺ layer 116, which has a higher doping density than the N-well layer 114, is formed in a sensor region over the whole of the top of the N-well layer 114. An NSG layer 120 and a BPSG layer 122, which are insulating layers, are formed on the top of the N⁺ layer 116. The metal layer 126, which serves as an electrode, is formed in a pre-specified electrode region on the top of the BPSG layer 122. The N⁺ layer 116 and the metal layer 126 are conducted between via the tungsten plug 124 that fills the contact hole 123. A PV-SiN layer 128 is formed on the tops of the BPSG layer 122 and the metal layer 126.

Light that is incident on the BPSG layer 122 passes through the BPSG layer 122 and the NSG layer 120, then passes through the N⁺ layer 116, is incident on the N-well layer 114, and reaches the PN junction interface between the N-well layer 114 and the P-sub layer 112. When the light reaches the PN junction interface, charges 130 are excited, and the excited charges 130 are sensed via the N⁺ layer 116. Thus, the light detection component 100 functions as a light detection component.

In general, a high resolution is requested for light sensors such as ambient light sensors and the like.

However, with the related art light detection component 100 illustrated in FIG. 6 and FIG. 7, there is a problem with variations in sensor sensitivity arising within and between semiconductor component device chips. In particular, variations in sensor sensitivity are a problem when the related art light detection component 100 is integrated, such as in an ambient light sensor.

### SUMMARY

The present invention is proposed in order to solve the problems described above, and an object of the present invention is to provide a semiconductor component and a semiconductor component fabrication method capable of reducing variations in light sensor sensitivity.

In order to achieve the object described above, a first aspect of the present invention provides a semiconductor component including:

a semiconductor substrate of a first conduction type;

a semiconductor layer of a second conduction type that is formed on the semiconductor substrate and is PN-joined with the semiconductor substrate;

an insulator layer laminated on the semiconductor layer;

a metal layer laminated on the insulator layer at a pre-specified region;

a semiconductor of the second conduction type at a side of the semiconductor layer at which the insulating layer is laminated, the semiconductor being formed directly under the metal layer such that incident light that is incident from the metal layer side is not illuminated onto the semiconductor layer, and the semiconductor containing more impurities than the semiconductor layer; and

a conduction portion that conducts between the metal layer and the semiconductor.

A second aspect of the present invention provides a method of fabricating a semiconductor component, the method including:

forming, on a semiconductor substrate of a first conduction type, a semiconductor layer of a second conduction type that is PN-joined with the semiconductor substrate;

forming, at a side of the semiconductor layer that is opposite from a side thereof that contacts the semiconductor substrate, a semiconductor of the second conduction type in a pre-specified region on which incident light that is incident on the semiconductor layer is not to be illuminated, the semiconductor containing more impurities than the semiconductor layer;

laminating an insulator layer on the semiconductor layer and the semiconductor;

forming an aperture portion in the insulator layer that is laminated in a region over the semiconductor;

forming a conduction portion in the aperture portion; and

laminating a metal layer on the insulator layer that covers the pre-specified region.

According to the present invention, an effect is provided in that variations in light sensor sensitivity may be reduced.

### BRIEF DESCRIPTION OF THE DRAWINGS

Exemplary embodiments of the present invention will be described in detail based on the following figures, wherein:

FIG. 1 is a plan view illustrating an example of schematic structure of a light detection component of an ambient light sensor, which is a semiconductor component relating to an exemplary embodiment;

FIG. 2 is a sectional diagram illustrating an example of a section taken along line A-A of the light detection component of an ambient light sensor illustrated in FIG. 1, which is the semiconductor component relating to the exemplary embodiment;

FIG. 3 is an explanatory view for describing a fabrication method of the semiconductor component relating to the exemplary embodiment;

FIG. 4 is an explanatory view for describing the fabrication method of the semiconductor component relating to the exemplary embodiment;

FIG. 5 is a sectional diagram illustrating another example of the section taken along line A-A of the light detection component of an ambient light sensor illustrated in FIG. 1, which is the semiconductor component relating to the exemplary embodiment;

FIG. 6 is a plan view illustrating an example of schematic structure of a light detection component of a related art ambient light sensor; and

FIG. 7 is a sectional diagram illustrating an example of a section taken along line B-B of the light detection component of the related art ambient light sensor illustrated in FIG. 6.

### DETAILED DESCRIPTION

Herebelow, a semiconductor component of an exemplary embodiment of the present invention is described in detail with reference to the attached drawings. Herein, as a concrete example of the semiconductor component relating to the exemplary embodiment of the present invention, a light detection component 10 of an ambient light sensor that is formed of a P-type semiconductor (hereinafter referred to simply as the light detection component 10) is described.

Structure of the Light Detection Component

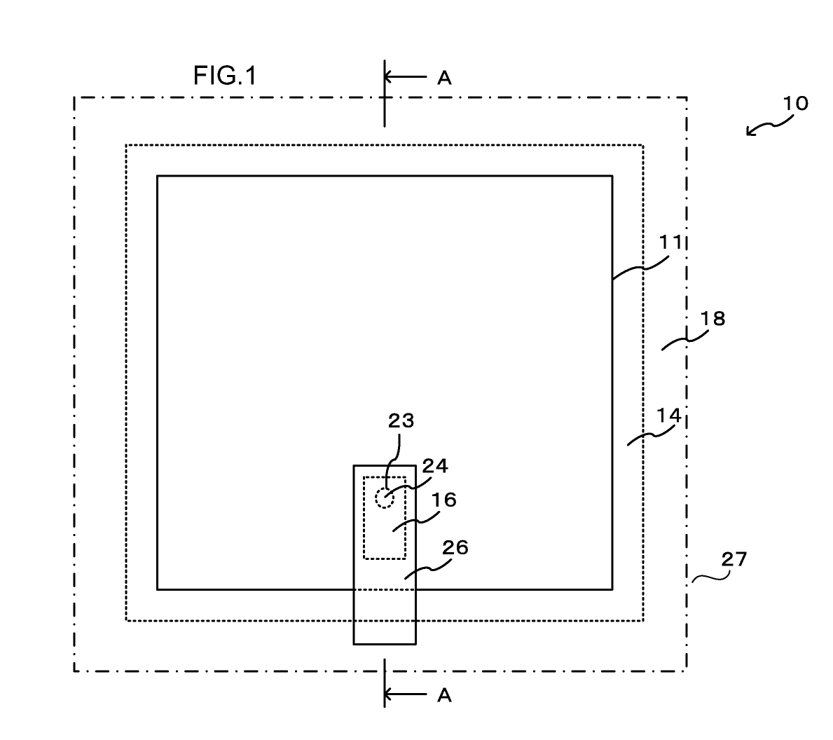

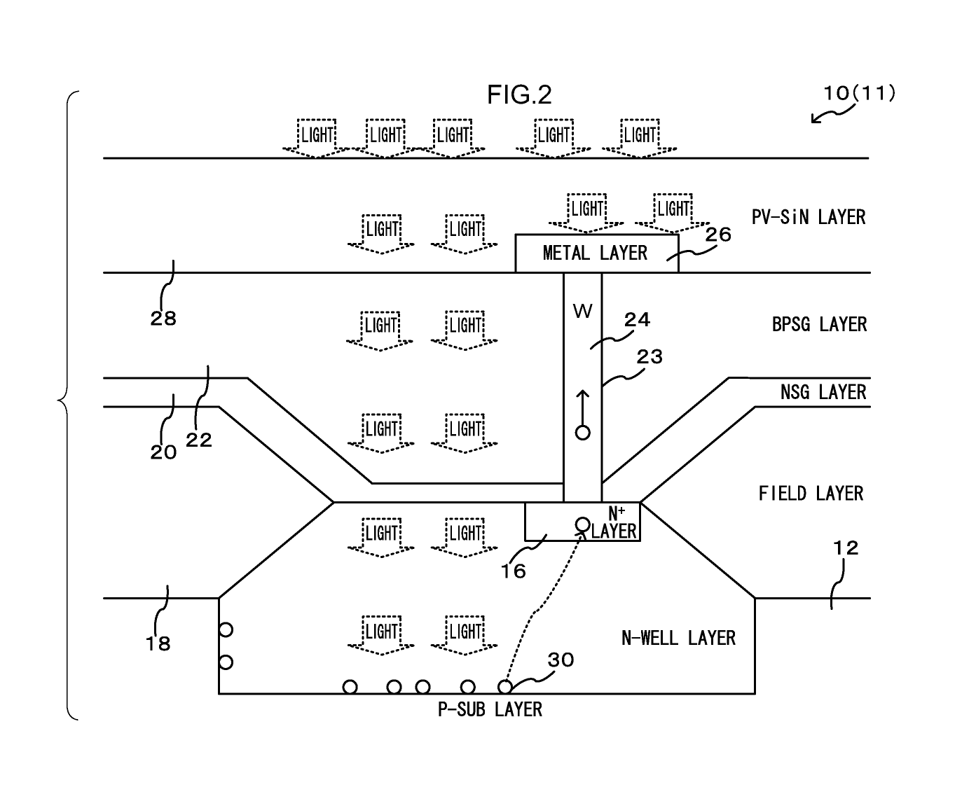

An example of the light detection component is illustrated in FIG. 1 and FIG. 2. FIG. 1 is a plan view illustrating an example of schematic structure of the light detection component 10 of the present exemplary embodiment, viewed from a side from which light is incident. FIG. 2 is a sectional diagram illustrating an example of a section taken along line A-A of the light detection component 10 of the present exemplary embodiment.

As illustrated in FIG. 1, the light detection component 10 of the present exemplary embodiment is provided with a structure in which, if viewed from the side from which light is incident, a field layer 18 is formed inside a metal layer 27, which is an anode electrode, an N-well layer 14 is formed inside the field layer 18, and a sensor region 11, which is a light detection portion, is formed inside the N-well layer 14. Further structure is provided in which a metal layer 26 is formed so as to cover portions of each of the sensor region 11, the N-well layer 14 and the field layer 18. An N⁺ layer 16 is formed in a region below the metal layer 26. In the present exemplary embodiment, as illustrated in FIG. 1, the N⁺ layer 16 is formed only in the region below the metal layer 26. Structure is further provided in which a contact hole 23 is formed in the metal layer 26, and a plug 24 is formed in the contact hole 23.

The structure of the light detection component 10 is described in further detail with reference to FIG. 2.

In the light detection component 10 of the present exemplary embodiment, an N-well layer (semiconductor layer) 14 is formed on a P-sub layer (semiconductor substrate) 12. The P-sub layer 12 is a silicon substrate whose conduction type is P type, and functions as an anode. Although not illustrated in FIG. 2, in the present exemplary embodiment, the metal layer 27 that is the anode electrode is laminated on a BPSG layer 22. That is, the metal layer 27 is laminated at the same position (depth) as the metal layer 26 in a depth direction in which the layers are formed (the vertical direction in FIG. 2). The metal layer 27 conducts with the P-sub layer 12 via the tungsten (W) plug 24 that is formed in the contact hole. The N-well layer 14 is PN-joined with the P-sub layer 12, and is a semiconductor whose conduction type is N⁻ type. Further impurities are implanted into a top portion of the N-well layer 14 by ion implantation or the like. Thus, the N⁺ layer (semiconductor) 16 with a higher doping density than the N-well layer 14 is formed. The N⁺ layer 16 is formed in a region whose top is covered by the metal layer 26. The N-well layer 14 and the N⁺ layer 16 function as a cathode.

An NSG (non-doped silicate glass) layer 20 that functions as an insulation layer and the BPSG (boro-phospho silicate glass) layer 22 are formed on the top of the N-well layer 14 and the N+ layer 16.

The metal layer 26, which functions as a cathode electrode, is formed in an electrode region on the top of the BPSG layer 22. In the present exemplary embodiment, the metal layer 26 is formed so as to cover the whole of the region in which the N+ layer 16 is formed. The N+ layer 16 and the metal layer 26 conduct via the plug 24 of tungsten (W) that is formed in the contact hole 23.

A PV-SiN layer 28 (a silicon nitride film) is formed over the top of the BPSG layer 22 and the metal layer 26.

In the light detection component 10 of the present exemplary embodiment, the field layer 18, which is a field oxide film, is formed in a field region excluding the sensor region 11.

When light that is incident on the surface of the light detection component 10 passes through the PV-SiN layer 28, because the metal layer 26 does not transmit light, the light is blocked by the surface of the metal layer 26 in the region in which the metal layer 26 is formed. Therefore, the light is not transmitted to layers below the region in which the metal layer 26 is formed. On the other hand, in the region in which the metal layer 26 is not formed, the light passes through the PV-SiN layer 28, passes through the BPSG layer 22 and the NSG layer 20, is incident on a region of the N-well layer 14 at which the N+ layer 16 is not formed, and reaches the PN junction interface.

When the light is illuminated on the PN junction interface between the P-sub layer 12 and the N-well layer 14, electrons and holes are produced and charges 30 are excited. The excited charges 30 are attracted to the N+ layer 16, and are drawn out to the metal layer 26 via the plug 24.

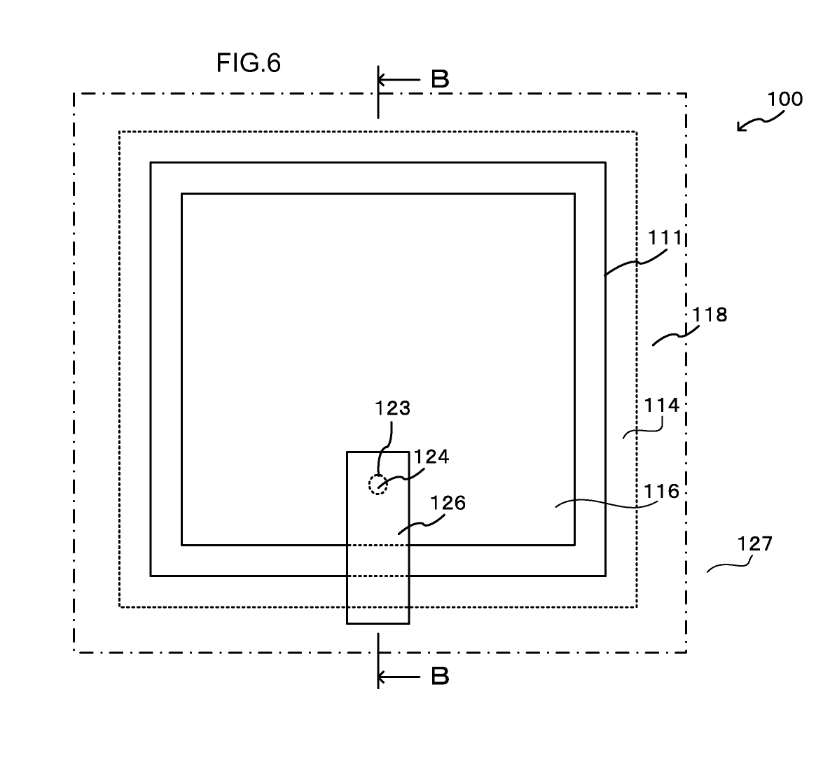

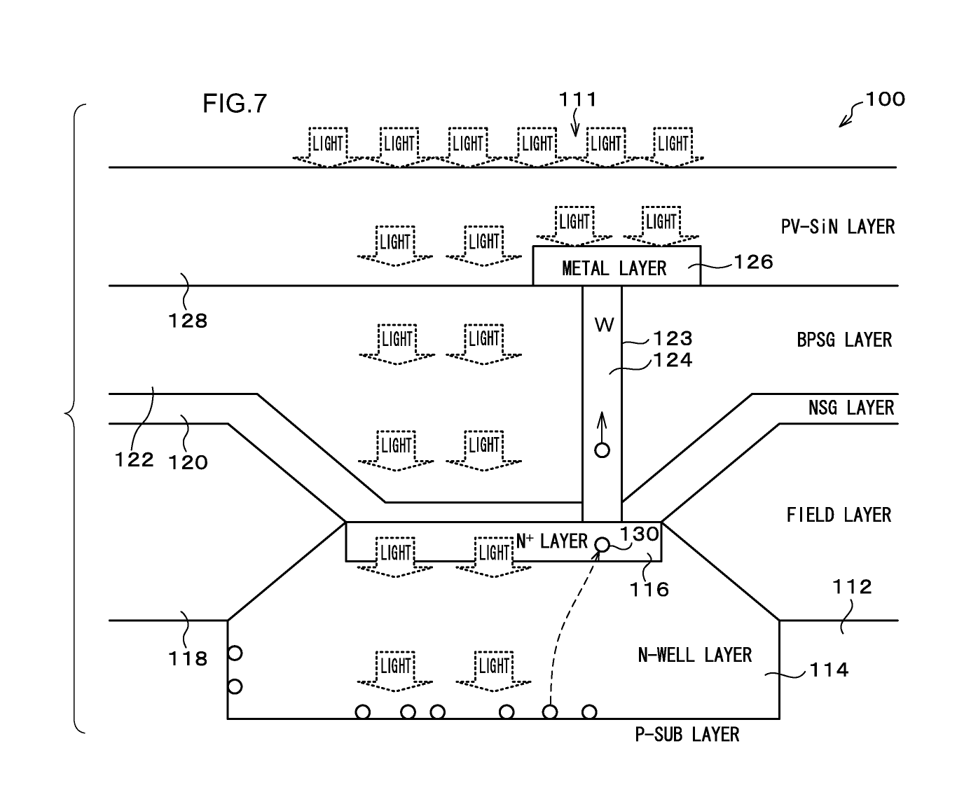

In general, when the N+ layer 16 is formed, crystal defects may occur in the layer. If crystal defects occur in the N+ layer 16, then when light passes through the N+ layer 16, light that reaches the PN junction interface is non-uniform because of the crystal defects, and sensor sensitivity may be inconsistent. Therefore, for example, in the light detection component 100 of the related art that is illustrated in FIG. 6 and FIG. 7, there is a problem with variations in sensor sensitivity. By contrast, in the light detection component 10, the N+ layer 16 is formed in the region below the metal layer 26 that does not transmit light, which is to say a region on which light illuminated from the upper side illustrated in FIG. 1 (the light illustrated in FIG. 2) is not incident. Therefore, the light that is incident on the light detection component 10 reaches the PN junction interface without passing through the N+ layer 16. Because the light reaching the PN junction interface is uniform, variations in sensor sensitivity are suppressed.

Light Detection Component Fabrication Method

Next, a fabrication method of the light detection component 10 is described.

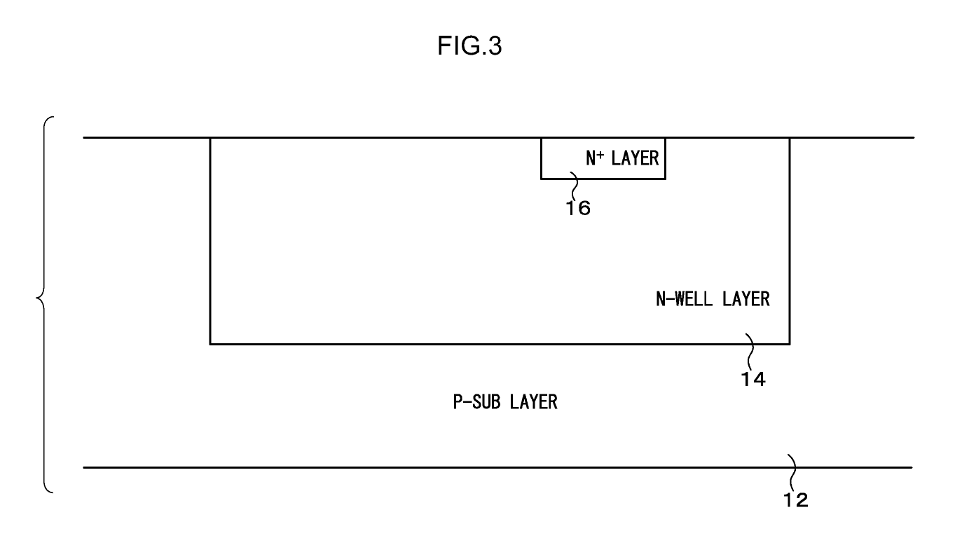

First, as illustrated in FIG. 3, a region at which the N-well layer 14 is to be formed is masked and etched, at the side of the P-sub layer 12 on which light is to be illuminated, to form the region at which the N-well layer 14 is to be formed. Regions apart from this region are masked, and the N⁻-type N-well layer 14 is formed by epitaxial growth or the like. At a region of the surface of the N-well layer 14 at which light is not to be incident (the region that is to be below the metal layer 26), impurities of phosphorus, arsenic or the like are ion-implanted, the implanted impurities are activated, and the N⁺ layer 16 is formed.

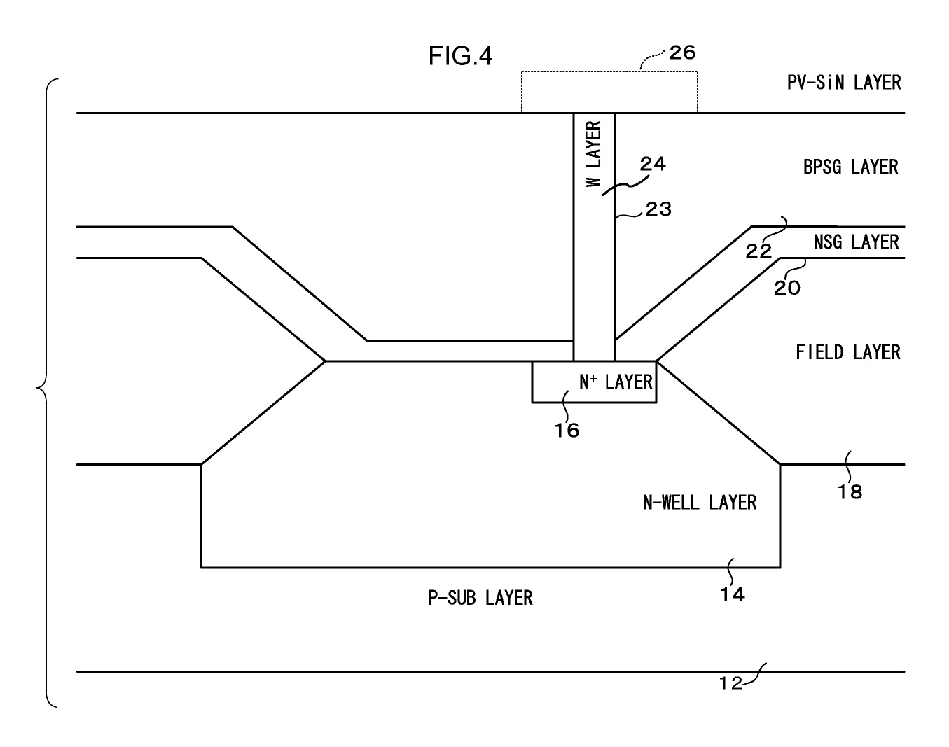

Then, as illustrated in FIG. 4, a field oxide layer is formed on the surface of the N-well layer 14 and the N⁺ layer 16, the field oxide layer is selectively oxidized by a selective oxidation process or the like such as, for example, LOCOS (LOCal Oxidation of Silicon) or suchlike, and the field layer 18 is formed. The NSG layer 20 and the BPSG layer 22 are formed on the N-well layer 14 and the field layer 18 by, for example, a CVD process or the like, and the contact hole 23 reaching to the N⁺ layer 16 is formed through the thus-formed NSG layer 20 and BPSG layer 22. Tungsten is deposited into the contact hole 23 and the plug 24 is formed.

Then, the metal layer 26 is formed on the BPSG layer 22 in a pre-specified region at which the contact hole 23 and the plug 24 are formed. Thereon, the PV-SiN layer 28 is formed over the whole area of the light detection component 10. Thus, the light detection component 10 of the present exemplary embodiment that is illustrated in FIG. 1 and FIG. 2 is fabricated.

As described above, in the light detection component 10 of the present exemplary embodiment, the N+ layer 16 is formed in a region below the metal layer 26 that does not transmit light, which is to say the region of the top of the N-well layer 14 on which light is not to be incident, and the N+ layer 16 is not formed at the region of the top of the N-well layer 14 on which light is to be incident. Hence, light that is incident on the light detection component 10 reaches the PN junction interface between the P-sub layer 12 and the N-well layer 14 and excites charges without passing through the N⁺ layer 16. In this light detection component 10 of the present exemplary embodiment, because light that reaches the PN junction interface reaches the PN junction interface without being affected by crystal defects in the N⁺ layer 16, variations in sensor sensitivity may be suppressed while the sensitivity of sensing is maintained. When the light detection component 10 is integrated on a chip and an ambient light sensor is plurally provided with such chips, variations in sensor sensitivity between the chips may be suppressed. Furthermore, causes of operational problems when the light detection component 10 is modularized may be suppressed.

In the present exemplary embodiment, as described above, the N⁺ layer 16 is not formed in the region on which light is incident. Therefore, compared to the N⁺ layer 116 of the related art light detection component 100, the size of the N⁺ layer 16 is smaller, and the attraction sensitivity of excited charges is reduced. However, values corresponding to incident light are defined for an ambient light sensor. Therefore, the definition of currents corresponding to wavelengths of light (for example, a current value of some mV for a light wavelength of some nm or the like) may be altered such that required current values are provided.

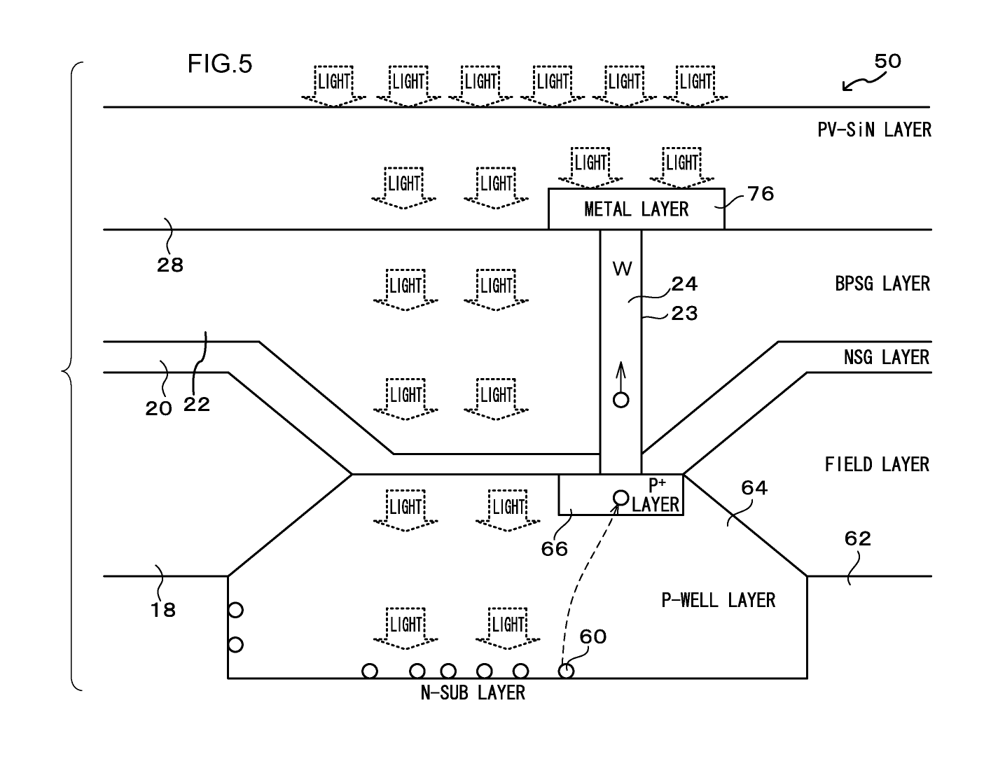

The above-described exemplary embodiment is not limiting to the present invention, and modifications are possible within a technical scope not departing from the spirit of the present invention. For example, a light detection component 50 as illustrated in FIG. 5 may be formed. In the light detection component 50, a structure may be formed that is provided with an N-sub layer 62 whose conduction type is N type that serves as a silicon substrate instead of the aforementioned P-sub layer 12, a P-well layer 64 whose conduction type is P type instead of the N-well layer 14, and a P⁺ layer 66 containing a higher density of impurities than the P-well layer 64 instead of the N⁺ layer 16. In the light detection component 50, similarly to the light detection component 10, the P⁺ layer 66 is formed at a region on which light is not illuminated below a metal layer 76 that serves as an anode electrode. Therefore, charges excited by light that reaches the PN junction interface between the N-sub layer 62 and the P-well layer 64 without passing through the P⁺ layer 66 are drawn into the metal layer 76 by the P⁺ layer 66 and the plug 24. Therefore, variations in sensor sensitivity may be suppressed. Thus, an N⁺ layer or a P⁺ layer that attracts charges may be formed at a region below a metal layer that functions as a cathode electrode or an anode electrode such that light is illuminated onto a PN junction interface without passing through the N⁺ layer or P⁺ layer. As further examples: the aforementioned NSG layer 20 and BPSG layer 22 are examples of insulating layers and other insulating layer or the like may be used provided they feature the insulating function; and the plug 24 is not limited to a tungsten plug and may be another conductive material provided it can conduct between the N⁺ layer 16 and the metal layer 26.

The light detection component 10 of the present exemplary embodiment is preferable for use in an ambient light sensor and has therefore been described as a light detection component to be used in an ambient light sensor. However, this is not to be limiting, and the light detection component 10 may be used as a light detection component (photodiode) of a different sensor.

What is claimed is:

1. A semiconductor component comprising:
a semiconductor substrate of a first conduction type;
a semiconductor layer of a second conduction type that is formed on the semiconductor substrate and is PN-joined with the semiconductor substrate;
an insulator layer laminated on the semiconductor layer;
a metal layer laminated on the insulator layer at a pre-specified region;
a semiconductor of the second conduction type at a side of the semiconductor layer at which the insulating layer is laminated, the semiconductor being formed directly under the metal layer such that incident light that is incident from the metal layer side is not illuminated onto the semiconductor layer, and the semiconductor containing more impurities than the semiconductor layer; and
a conduction portion that conducts between the metal layer and the semiconductor.

2. The semiconductor component of claim 1, wherein the semiconductor is covered by the metal layer.

3. The semiconductor component of claim 1, wherein the semiconductor layer is a well layer.

4. The semiconductor component of claim 1, wherein the conduction portion is formed in a contact hole formed in the insulating layer.

5. A method of fabricating a semiconductor component, the method comprising:
forming, on a semiconductor substrate of a first conduction type, a semiconductor layer of a second conduction type that is PN-joined with the semiconductor substrate;
forming, at a side of the semiconductor layer that is opposite from a side thereof that contacts the semiconductor substrate, a semiconductor of the second conduction type in a pre-specified region on which incident light that is incident on the semiconductor layer is not to be illuminated, the semiconductor containing more impurities than the semiconductor layer;
laminating an insulator layer on the semiconductor layer and the semiconductor;
forming an aperture portion in the insulator layer that is laminated in a region over the semiconductor;
forming a conduction portion in the aperture portion; and
laminating a metal layer on the insulator layer that covers the pre-specified region.
